(19) United States
(12) Patent Application Publication
(10) Pub. No.: US 2011/0211396 A1
(43) Pub. Date: Sep. 1, 2011

(54) NONVOLATILE SEMICONDUCTOR MEMORY DEVICE AND OPERATION METHOD THEREOF

(75) Inventor: Hidenori TAKEUCHI, Kanagawa (JP)

(73) Assignee: RENESAS ELECTRONICS CORPORATION, Kanagawa (JP)

(21) Appl. No.: 13/036,587

(22) Filed: Feb. 28, 2011

(30) Foreign Application Priority Data
Feb. 26, 2010 (JP) 2010-041938

(51) Int. Cl. G11C 16/06

(52) U.S. Cl. 365/185.22

(57) ABSTRACT

The erase operation of a nonvolatile semiconductor memory is executed by a method including applying an erase pulse to a data erase area in a memory cell array, determining whether the threshold voltage of a memory cell arranged in the data erase area reaches an erase level and outputting a verify result, and determining whether a new erase pulse is applied or a state is shifted to a wait state based on the verify result. The new erase pulse is applied when the threshold voltage does not reach the erase level and the application of the new erase pulse is prohibited and the wait operation is performed when the threshold voltage reaches the erase level.

### CROSS-REFERENCE TO RELATED APPLICATIONS

The disclosure of Japanese Patent Application No. 2010-41938 filed on Feb. 26, 2010 including the specification, drawings and abstract is incorporated herein by reference in its entirety.

### BACKGROUND

1. Field of the Invention

The present invention relates to a nonvolatile semiconductor memory device and a method of operating the nonvolatile semiconductor device.

2. Description of Related Art

A semiconductor memory which is capable of freely erasing, writing and reading data and in which information stored therein is nonvolatile even if a power supply is turned off (hereinafter referred to as a nonvolatile semiconductor memory device) is mounted on various electronic appliances. Along with a demand for downsizing, lightening, and sophisticating such an electronic appliance, there has been demanded a nonvolatile semiconductor memory device whose chip area is prevented from increasing and which can store a large amount of information.

As such a nonvolatile semiconductor memory device, there has been known a nonvolatile semiconductor memory device which uses a trap for a charge storage layer provided in an insulation film (hereinafter referred to as a charge-storage-layer storage device). As an example of the charge-storage-layer storage device, there has been known a MONOS nonvolatile semiconductor memory device using a metal oxide nitride oxide semiconductor (MONOS).

The MONOS nonvolatile semiconductor memory device with a MONOS cell has been mounted also on an electronic appliance such as on-board equipment required to have a high reliability. High reliability has been required for the data hold characteristic of the MONOS nonvolatile semiconductor memory device. The data hold characteristic needs ensuring by accurately setting a writing level and an erasing level to obtain a sufficient margin of the data hold characteristic. To this end, in the MONOS cell for trapping a charge in a charge storage layer, an initial drift occurring at an erase level caused by rearrangement and recombination of an electron and a hole needs suppressing.

In the above MONOS nonvolatile semiconductor memory device, a so-called “verify operation” is widely used to set a threshold level of an erase operation to a target setting electric potential. In the verify operation, the level of the threshold level is confirmed after the writing and erasing pulse is applied in the write operation and the erase operation and the operation of application of the writing and the erasing pulse is repeated so that the threshold level reaches the target setting electric potential. Also in a cell for injecting a hole, a technique related to an erase verify operation for confirming an erase operation state after an erase pulse is applied to create a sufficient erase operation state is known (refer to Japanese Application Publication No. 2008-293635, for example).

FIGS. 1A and 1B show erase loops in a technique described in Japanese Application Publication No. 2008-293635. As shown in FIGS. 1A and 1B, the erase loop may include one or more erase unit loopi (“i” is an integer of one or more). As shown in FIGS. 1A and 1B, the erase loopi may include an erase operation P1, a time delay operation P2, a verify read operation P3. The time delay operation P2 lies between the erase operation P1 and the verify reading operation P3. The time delay operation P2 allows a timer margin so that a charge is rearranged and recombined in a charge trap layer. The threshold voltage (Vth) of a program cell can be changed during the time delay operation P2.

In the technique described in Japanese Application Publication No. 2008-293635, the time delay operation is performed so that a charge is rearranged and recombined in a charge trap layer after the erase operation, thereafter, the verify reading operation is performed to realize an erase method whose operation characteristic is improved.

### SUMMARY

In the technique described in Japanese Application Publication No. 2008-293635, the erase operation P1, the time delay operation P2, and the verify reading operation P3 form a unit erase loop and are executed in this unit. At this point, the time delay operation P2 for stabilizing the state of the erase cell is executed between the erase operation P1 and the verify reading operation P3. In the technique described in Japanese Application Publication No. 2008-293635, the erase operation needs to be executed a plurality of times in a small unit to accurately set an erase level and prevent an over-erase contributing to the deterioration of the hold characteristic.

However, if retry occurs and the unit erase loop, which is composed of the erase operation P1, the time delay operation P2, and the verify reading operation P3, is executed a plurality of times, it takes a long time by the time the erasing is completed.

The present invention seeks to solve one or more of the above problems, or to improve upon those problems at least in part.

In one embodiment, there is provided a method of operating a nonvolatile semiconductor memory, the method including the steps of (a) applying an erase pulse to a data erase area in a memory cell array, (b) determining whether the threshold voltage of a memory cell arranged in the data erase area reaches an erase level and outputting a verify result, (c) determining whether a new erase pulse is applied or a state is shifted to a wait state based on the verify result; and (d) measuring the wait time during which an erase voltage is not applied in response to a wait command. The step (b) includes a step of determining whether the threshold voltage reaches the erase level before a state is shifted to the wait state after an application period during which the erase pulse is applied passes. The step (c) includes a step of issuing instructions to apply the new erase pulse to the data erase area when the threshold voltage does not reach the erase level and a step of issuing instructions to prohibit the new erase pulse being applied and issuing the wait command when the threshold voltage reaches the erase level.

To realize the above erase operation, there is provided a nonvolatile semiconductor memory device including a driver circuit configured to apply an erase pulse to a data erase area in a memory cell array, a verify circuit configured to determine whether the threshold voltage of a memory cell arranged in the data erase area reaches an erase level and output a verify result, a control circuit configured to determine whether a new erase pulse is applied or a state is shifted to a wait state based on the verify result, and a wait circuit configured to measure the wait time during which an erase voltage is not applied in response to a wait command from the control circuit. The verify circuit determines whether the threshold voltage reaches the erase level before a state is shifted to the wait state after an application period during which the erase pulse is applied passes. The control circuit instructs the driver circuit to apply the new erase pulse to the data erase area when the threshold voltage does not reach the erase level. Furthermore, the control circuit instructs the driver circuit to prohibit the application of the new erase pulse and issues the wait command to the wait circuit when the threshold voltage reaches the erase level.

If an advantage obtained by a representative invention among the inventions disclosed in the present application is briefly described, the time required for erase operation can be shortened while deterioration in the hold characteristic of a nonvolatile semiconductor memory is being reduced.

### BRIEF DESCRIPTION OF THE DRAWINGS

FIG. 1A shows an erase loop in a related technique;

FIG. 1B shows an erase loop in a related technique;

FIG. 2 is a block diagram exemplifying the configuration of a nonvolatile semiconductor memory device 1;

FIG. 3A exemplifies the configuration of a nonvolatile memory cell and a voltage arrangement at the time of an erasing operation;

FIG. 3B shows a timing chart exemplifying the erase operation;

FIG. 3C shows a schematic diagram exemplifying the erase operation;

FIG. 4A exemplifies the configuration of the nonvolatile memory cell and a voltage arrangement at the time of a writing operation;

FIG. 4B shows a schematic diagram exemplifying the writing operation;

FIG. 5 exemplifies the configuration of the nonvolatile memory cell and a voltage arrangement at the time of a reading operation;

FIG. 6 shows a flow chart exemplifying the erase operation of the nonvolatile semiconductor memory device 1;

FIG. 7 shows a timing chart exemplifying the waveform of each signal;

FIG. 8 shows a schematic diagram exemplifying the shift of the threshold Vt from the start of execution of the erase operation to the end of erase;

FIG. 9 is an enlarged view of the initial variation portion;

FIG. 10 is a reference for comparing the technique described in the above Japanese Application Publication No. 2008-293635 with that in the present embodiment;

FIG. 11 is a block diagram exemplifying the configuration of a nonvolatile semiconductor memory device 1 according to the second embodiment;

FIG. 12 shows a flow chart exemplifying the operation of the second embodiment; and

FIG. 13 shows a timing chart exemplifying the operation of the second embodiment.

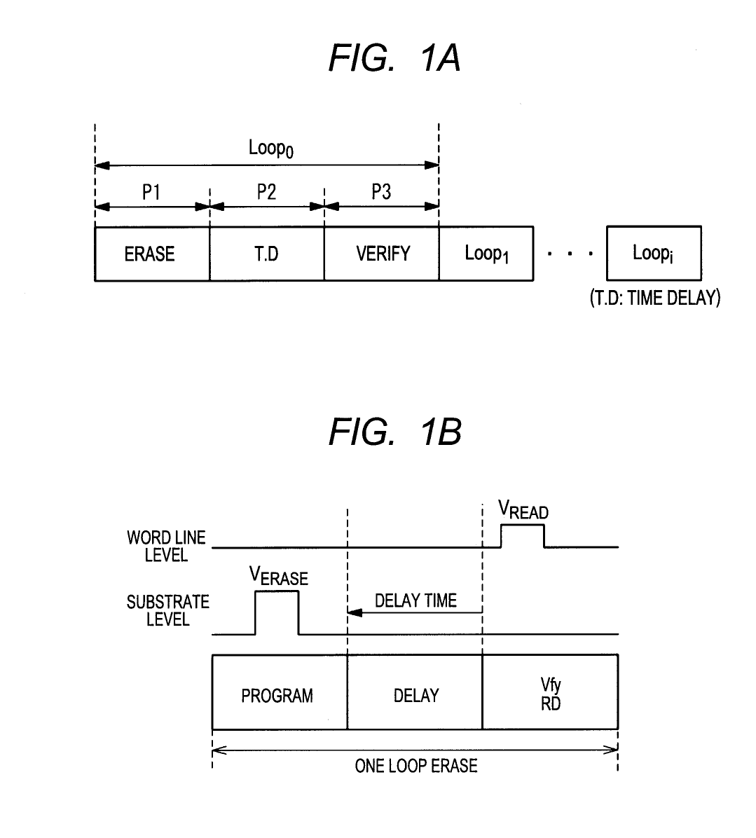

### DETAILED DESCRIPTION

### First Embodiment

An embodiment of the present invention is described below with reference to the accompanied drawings. In the drawings for describing the embodiments, in principle, the same reference numerals and characters are given to the same components, and any repetitive description thereof is omitted.

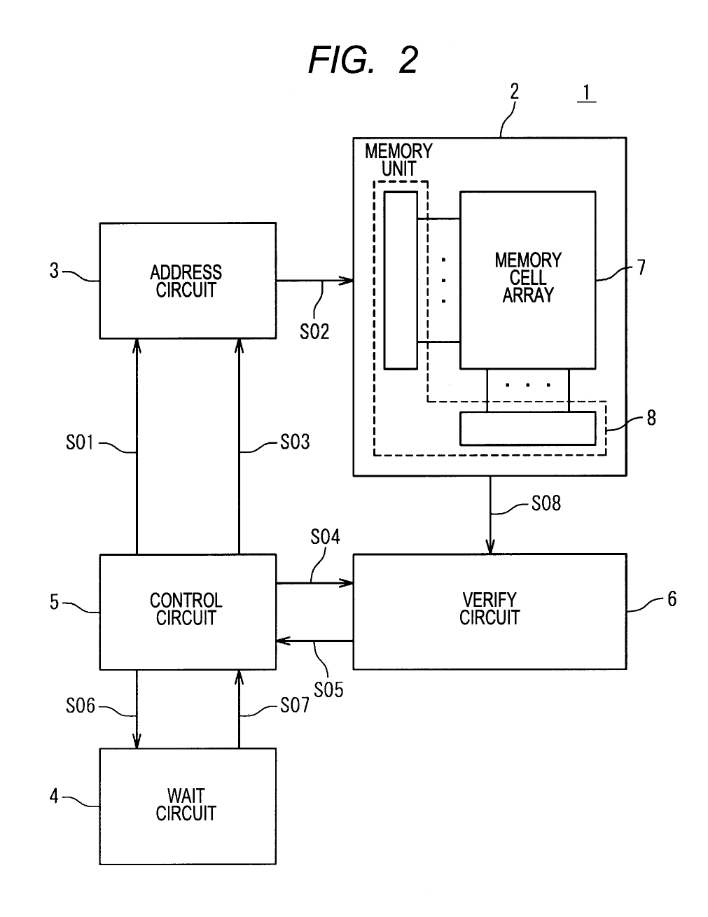

FIG. 2 is a block diagram showing an example of configuration of a nonvolatile semiconductor memory device 1 according to the present embodiment. The nonvolatile semiconductor memory device 1 according to the present embodiment includes a memory unit 2, an address circuit 3, a wait circuit 4, a control circuit 5, and a verify circuit 6.

The memory unit 2 holds written data and provides data according to a received command. As shown in FIG. 2, the memory unit 2 receives an address signal S02 supplied from the address circuit 3. The memory unit 2 supplies an output data S08 to verify circuit 6.

The memory unit 2 includes a memory cell array 7 and a drive circuit 8. The memory cell array 7 includes a plurality of memory cells. In the present embodiment, a plurality of Twin MONOS cells is arranged in the memory cell array 7. The drive circuit 8 is coupled to the memory cell array 7 and supplies a predetermined voltage to the electrodes and the diffusion layer of the Twin MONOS cells arranged in the memory cell array 7.

The address circuit 3 supplies the address signal S02 for identifying an area for erasing, writing, and reading data. The address circuit 3 receives an address selection signal S01 for an erase pulse and a verify address selection signal S03 which are supplied from the control circuit 5. The address circuit 3 generates the address signal S02 for an erase operation for the memory unit 2 based on the address selection signal S01 for an erase pulse. The address circuit 3 generates the address signal S02 used at the verify operation in which a target erase level is determined for the memory unit 2.

The wait circuit 4 supports timing control in the erase operation. The wait circuit 4 receives a wait start signal S06 supplied from the control circuit 5. The wait circuit 4 supplies a wait end signal S07 to the control circuit 5. The wait circuit 4 stands by for a predetermined time based on the wait start signal S06.

The control circuit 5 controls the operation for erasing, writing, and reading data for the memory unit 2. The control circuit 5 supplies a verify execution signal S04 to the verify circuit 6. The control circuit 5 receives a verify result signal S05 supplied from the verify circuit 6. The control circuit 5 generates the wait start signal S06 based on the verify result signal 505. The control circuit 5 releases a wait state based on the wait end signal S07 supplied from the wait circuit 4.

The verify circuit 6 determines whether the target erase level is reached based on the output data S08 after the erase of data in the memory unit 2 is executed and the wait state is released. The verify circuit 6 supplies the verify result signal S05 indicating the determination result to the control circuit 5.

The basic operation of the nonvolatile semiconductor memory device 1 is described below. The following four operations are discussed below: (1) erase, (2) write, (3) hold, and (4) read, as the basic operation of the above Twin MONOS nonvolatile semiconductor memory device. The names of the four states are used as representative ones. The writing and the erasing may be reversely called.

### (1) Erase Operation

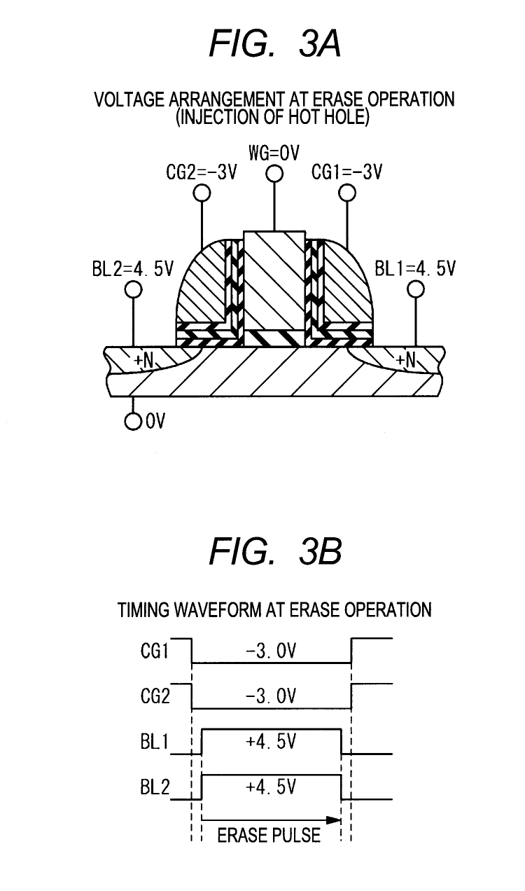

An operation for erasing written information is described. FIG. 3A shows a configuration of a memory cell provided for the nonvolatile semiconductor memory device 1 according to the present embodiment and exemplifies a voltage arrangement at the time of an erase operation. As shown in FIG. 3A, an electric potential of about 0 V is applied to a word gate electrode WG in the erase operation. A negative electric potential of about −3 V is applied to control gate electrodes CG1 and CG2. A positive electric potential of about 4.5 V is applied to source/drain diffusion layers BL1 and BL2. The voltage arrangement is changed to allow selectively erasing only the one. FIG. 3B shows a timing chart exemplifying the erase operation.

FIG. 3C shows a schematic diagram exemplifying the erase operation. Referring to FIG. 3C, a hot hole generated at a drain end is generated by a hot carrier and injected into a nitride film of an ONO laminated film on a selection side. Thereby, negative electric charges stored in the nitride film of the ONO laminated film are cancelled to erase data.

### (2) Write Operation

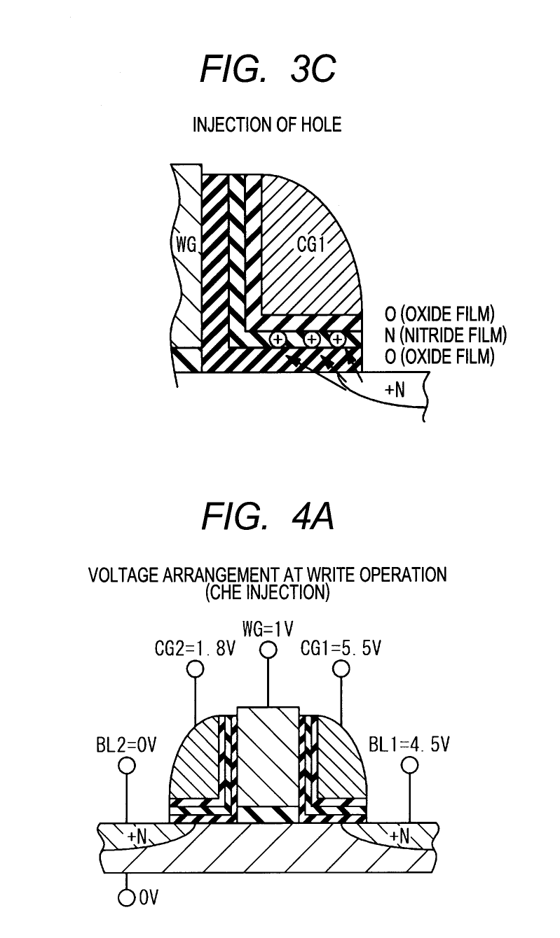

An operation for writing information into a memory cell is described. FIG. 4A shows a configuration of a memory cell provided for the nonvolatile semiconductor memory device 1 according to the present embodiment and exemplifies a voltage arrangement at the time of a write operation. As shown in FIG. 4A, a positive electric potential of about 1 V is applied to a word gate electrode WG when the write operation is executed. A positive electric potential of about 5.5 V is applied to one control gate electrode CG1 on a writing side (hereinafter referred to as “selection side”). A positive electric potential of about 1.8 V is applied to the other control gate electrode CG2 paired with the one control gate electrode CG1 on a non-writing side (hereinafter referred to as “non-selection side”). A positive electric potential of about 4.5 V is applied to a source/drain diffusion layer BL1 on the selection side. An electric potential of about 0 V is applied to a source/drain diffusion layer BL2 on the non-selection side.

FIG. 4B shows a schematic diagram exemplifying the writing operation. Referring to FIG. 4B, a hot electron generated in a channel region is injected into a nitride film of an ONO laminated film on the selection side. This is called a channel-hot-electron (CHE) injection. Thus, data are written into the memory cell.

### (3) Hold Operation

While the written information is being held, electric charges are held as electric charges of carriers injected into the nitride film of the ONO laminated film. Since a very small number of carriers moves to the insulation film of the ONO laminated film, the electric charges can be held in good condition even if voltage is not applied to the electrode.

### (4) Read Operation

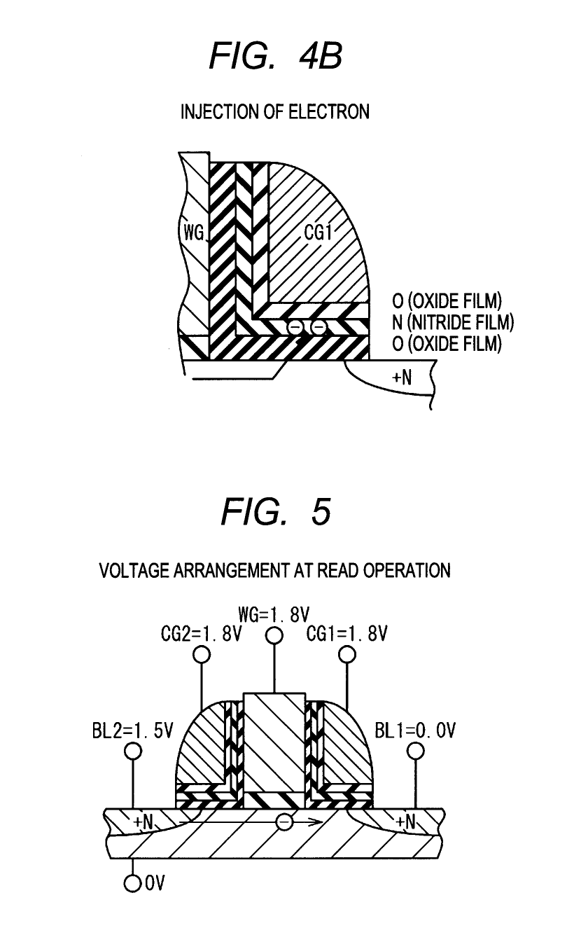

An operation for reading written information is described. FIG. 5 shows a configuration of a memory cell provided for the nonvolatile semiconductor memory device 1 according to the present embodiment and exemplifies a voltage arrangement at the time of a read operation. A positive electric potential of about 1.8 V is applied to a word gate electrode WG in read operation. A positive electric potential of about 1.8 V is applied to a control gate electrodes CG1 and CG2. An electric potential of about 0 V is applied to a source/drain diffusion layer BL1 on the selection side. An electric potential of about 1.5 V is applied to a source/drain diffusion layer BL2 on the non-selection side. The threshold of the memory cell transistor is detected in this condition. If negative electric charges are stored in the ONO laminated film on the selection side, the threshold becomes greater than that in a case where no negative electric charges are stored, so that the threshold is detected to allow reading the information written into the ONO laminated film on the selection side. The Twin MONOS cell can record two-bit information, one bit each into the word gate electrodes.

In the nonvolatile semiconductor memory device 1 according to the present embodiment, a reading current Ion of the memory cell is varied depending on whether holes are trapped in the nitride film of the ONO laminated film (charge storage film) or whether electrons are trapped therein. The reading current is determined to allow determining whether information is written. If an erase verify (the determination of an erase level) is performed, the control gate electrode on the selection side is set to any voltage.

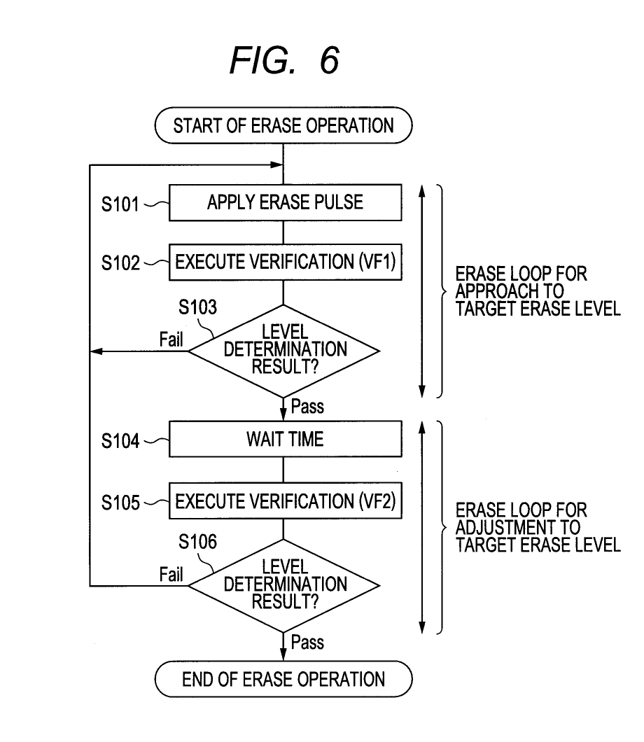

An erase operation in the nonvolatile semiconductor memory device 1 according to the present embodiment is described below. The nonvolatile semiconductor memory device 1 selects whether the erase pulse is applied again or waiting is performed by the wait circuit 6 based on the verify result signal S05 of the verify circuit 6. FIG. 6 shows a flow chart exemplifying the erase operation of the nonvolatile semiconductor memory device 1 according to the present embodiment.

When erase operation is started, the control circuit 5 supplies the address selection signal S01 for an erase pulse to the address circuit 3. The address circuit 3 identifies a data erasing area based on the address selection signal S01 for an erase pulse. The address circuit 3 supplies the address signal S02 indicating the address of the identified area to the memory unit 2.

Referring to FIG. 6, in step S101, the memory unit 2 receives the address signal S02 indicating the erasing address. The drive circuit 8 in the memory unit 2 applies the erase pulse to the cell in the area of the memory cell array 7 indicated in the address signal S02 in the voltage arrangement at the time of erase operation.

After the erase pulse is applied, the control circuit 5 supplies the verify address selection signal S03 to the address circuit 3. The address circuit 3 identifies the address of the erased area based on the verify address selection signal S03 and supplies the address signal S02 for sequentially reading the data of the area to the memory unit 2. The control circuit 5 supplies the verify execution signal S04 to the verify circuit 6.

In step S102, the verify circuit 6 conducts verification in response to the verify execution signal S04 supplied from the control circuit 5. At the time of executing the verification, data are sequentially read from the memory unit 2 by the address signal S02 supplied from the address circuit 3. The drive circuit 8 in the memory unit 2 reads data from the memory cell array 7 with the data changed to the control gate voltage corresponding to the target erase level in the verify operation and supplies the control gate voltage to the verify circuit 6 as the output data S08. The verify circuit 6 compares the output data S08 with the erase level. The verify circuit 6 supplies the verify result signal S05 indicating the comparison result to the control circuit 5.

In step S103, the control circuit 5 determines whether the verify result signal S05 is a signal indicating coincidence (Pass) or insufficiency (Fail). If the control circuit 5 determines that the verify result signal S05 indicates insufficiency (Fail), the processing retunes to step S101. If the control circuit 5 determines that the verify result signal S05 indicates Pass, the processing proceeds to step S104.

In step S104, if the verify result signal S05 indicates coincidence (Pass), the control circuit 5 supplies the wait start signal S06 to the wait circuit 4. The wait circuit 4 measures the preset time in response to the wait start signal S06. The wait circuit 4 supplies the wait end signal S07 to the control circuit 5 when the time passes. The control circuit 5 stops the operation such as the application of the erase pulse and the reading of data by the time the control circuit 5 receives the wait end signal S07. Wait time in the present embodiment refers to a period of time for which an initial variation caused by the rearrangement and recombination of between electrons and holes is prevented and stabilized in the nitride film of the ONO laminated film (charge storage film) in the Twin MONOS cell provided in the memory cell array 7 in the memory unit 2.

In step S105, the control circuit 5 supplies again the verify address selection signal S03 to the address circuit 3 in response to the wait end signal S07 supplied from the wait circuit 4. At this point, the control circuit 5 supplies the verify execution signal S04 to the verify circuit 6. Thereby, the control circuit 5 determines whether the erase cell after the wait operation reaches the target erase level.

The drive circuit 8 in the memory unit 2 reads data from the memory cell array 7 and supplies the data to the verify circuit 6 as the output data S08. The verify circuit 6 compares the output data S08 with the target erase level and supplies the verify result signal S05 indicating the comparison result to the control circuit 5.

In step S106, the control circuit 5 determines whether the verify result signal S05 is a signal indicating coincidence (Pass) or insufficiency (Fail). If the control circuit 5 determines that the verify result signal S05 indicates insufficiency (Fail), the processing retunes to step S101. If the control circuit 5 determines that the verify result signal S05 indicates coincidence (Pass), the processing ends.

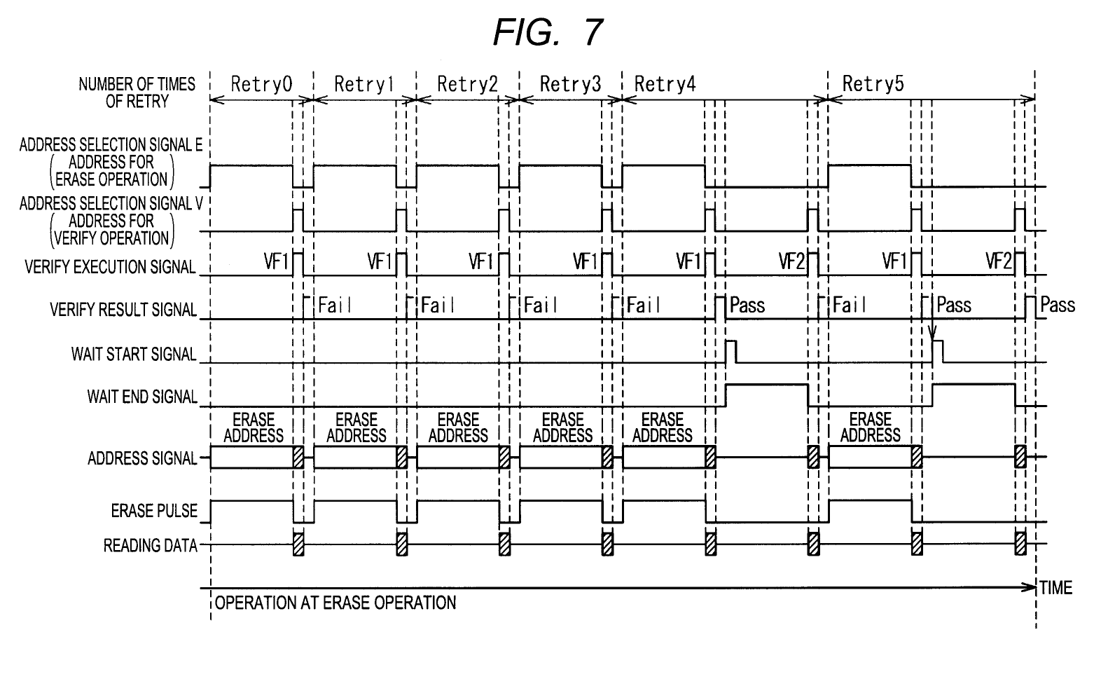

FIG. 7 shows a timing chart exemplifying the waveform of each signal in the operation exemplified in the above flow chart. The timing chart shown in FIG. 7 exemplifies operation in a case where erasing is continuously repeated four times after the erase operation starts and then the verify result signal S05 indicates coincidence (Pass).

As shown in FIG. 7, the wait start signal S06 is supplied in response to the verify result signal S05 when the verify result signal S05 indicates coincidence (Pass). The wait circuit 4 shifts the wait end signal S07 from a level Low as an inactive level to a level High as an active level in response to the wait start signal S06. At this point, the application of the erase pulse is stopped.

The wait circuit 4 shifts the wait end signal S07 from a level High as an active level to a level Low as an inactive level after the wait time passes. The control circuit 5 generates the verify address selection signal S03 and the verify execution signal S04 in response to the wait end signal S07. The verify circuit 6 executes verification again in response to the verify execution signal S04. As a result, if the verify result signal S05 indicates insufficiency (Fail), the erase pulse is applied again.

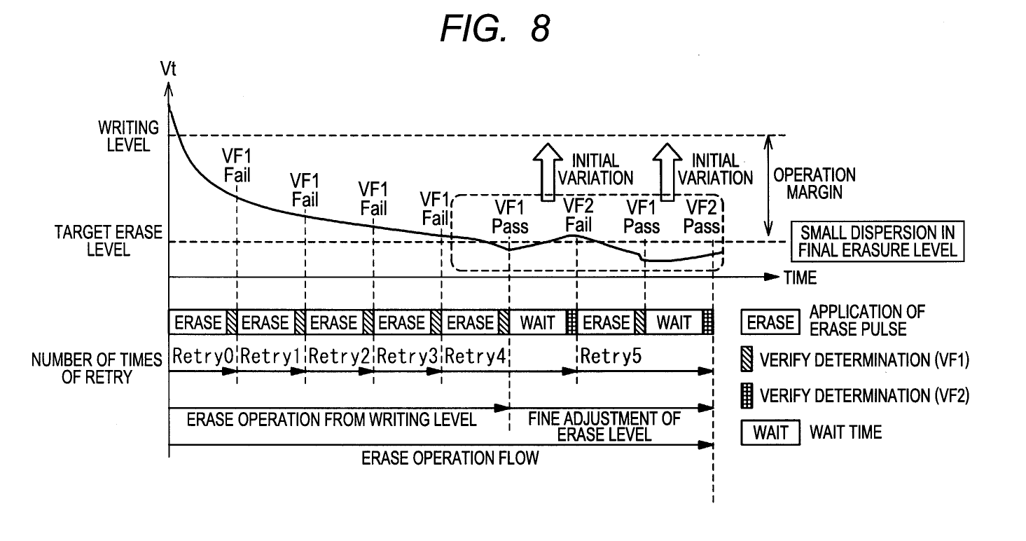

FIG. 8 shows a schematic diagram exemplifying the shift of the threshold Vt in the erase operation according to the present embodiment. FIG. 8 exemplifies the state of the threshold Vt shifting from a writing state to an erasing state for each retry. The nonvolatile semiconductor memory device 1 according to the present embodiment continuously executes the application of the erase pulse for a short period of time and verify after that until the target erase level is reached. Thereby, the time required for shifting from a writing cell state to an erasing cell state can be reduced.

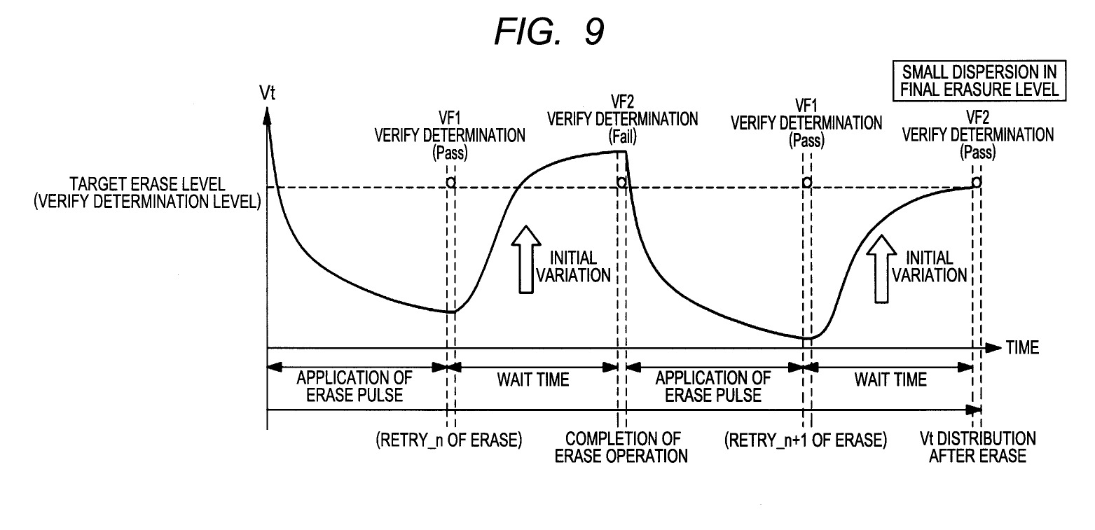

FIG. 9 is an enlarged view of the initial variation portion in FIG. 8. As described above, the wait circuit 4 takes a period of time for which an initial variation caused by the rearrangement and recombination of between electrons and holes is prevented and stabilized in the nitride film of the Twin MONOS cell ONO laminated film (charge storage film) as the wait time. Thereby, the erase level can be appropriately maintained against the initial variation.

### Referential Example

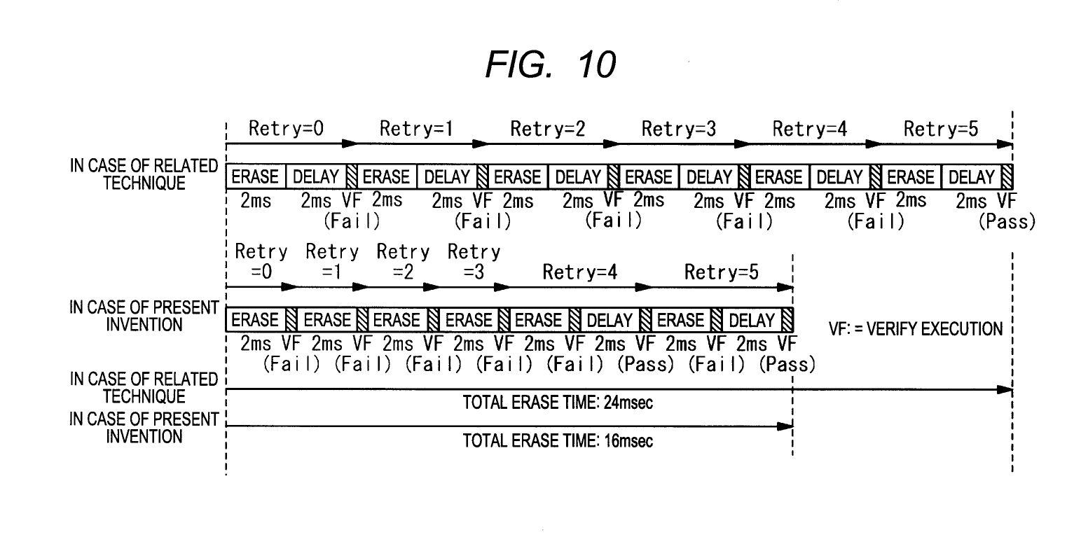

FIG. 10 is a reference for comparing the technique described in the above Japanese Application Publication No. 2008-293635 with that in the present embodiment. FIG. 10 describes the time required for erasing: an erase pulse application time of 2 ms and wait time (the delay time in the technique discussed in Japanese Application Publication No. 2008-293635) of 2 ms. The erase operation is also exemplified therein in a case where the number of times of retry is five, as a characteristic of the erase cell.

As shown in FIG. 10, in the technique described in the above Japanese Application Publication No. 2008-293635, the time required until erasing is completed is 24 ms. In the nonvolatile semiconductor memory device 1 according to the present embodiment, erasing is completed in 16 ms. Thus, the technique described in the present embodiment can complete erasing within 66% of the time required by the technique described in Japanese Application Publication No. 2008-293635. The erasing can be effectively completed in a case where the wait time or the number of time of retry is increased due to the characteristics of an element.

As described above, the nonvolatile semiconductor memory device 1 according to the present embodiment is immune to the variation of the erase level due to a peculiar initial variation of the MONOS cell and can create an accurate erase level. The application of the erase pulse is repeated to allow the state to be quickly shifted to the vicinity of the target erase level. Verification is performed again in a stable state in the vicinity of the target erase level using wait time to enable maintaining a non-dispersive stable state with respect to the target erase level.

In other words, in the nonvolatile semiconductor memory device 1 according to the present embodiment, the application of the erase pulse for a short period of time is repeated many times to finely shift the state to the target erase level, so that the over-erasing occurred at the time of erasing can be made smaller than that in a case where the application of the erase pulse for a long period of time is repeated a few times in the related technique. After the target erase level is reached, the verification with wait time in consideration of the initial variation is executed in the present embodiment. An accurate erase level can be ensured to allow obtaining a large operation margin being a difference between a write level and an erase level, improving a holding characteristic of a MONOS memory.

### Second Embodiment

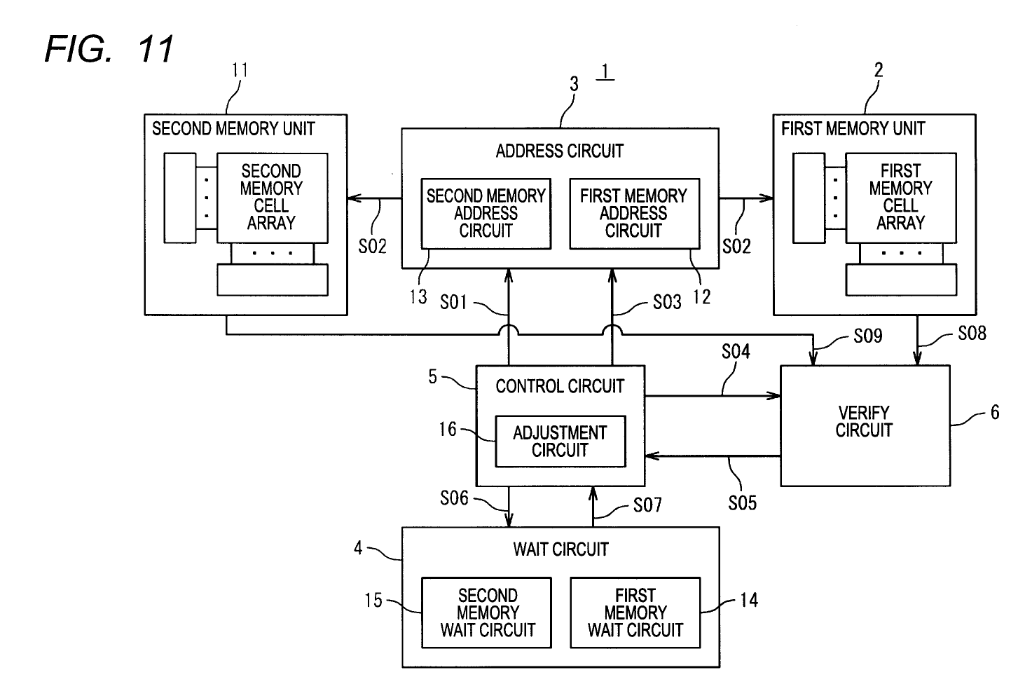

A second embodiment of the nonvolatile semiconductor memory device 1 according to the present invention is described below. FIG. 11 is a block diagram exemplifying the configuration of a nonvolatile semiconductor memory device 1 according to the second embodiment. The nonvolatile semiconductor memory device 1 according to the second embodiment includes a plurality of memory units (a memory unit 2 and a second memory unit 11). FIG. 11 exemplifies the nonvolatile semiconductor memory device 1 with two memory units, and this does not limit the number of the memory units in the present embodiment.

Referring to FIG. 11, the nonvolatile semiconductor memory device 1 according to the second embodiment further includes a second memory unit 11 added to the nonvolatile semiconductor memory device 1 according to the first embodiment. In the nonvolatile semiconductor memory device 1 according to the second embodiment, the address circuit 3 includes a first memory address circuit 12 for supplying the address signal S02 to the first memory unit 2 and a second memory address circuit 13 for supplying the address signal S02 to the second memory unit 11. The wait circuit 4 includes a first memory wait circuit 14 for supporting the control of the operation timing for the first memory unit 2 and a second memory wait circuit 15 for supporting the control of the operation timing for the second memory unit 11. The control circuit 5 includes an adjustment circuit 16 for controlling the timing of the erase operation of the first memory unit 2 and the second memory unit 11.

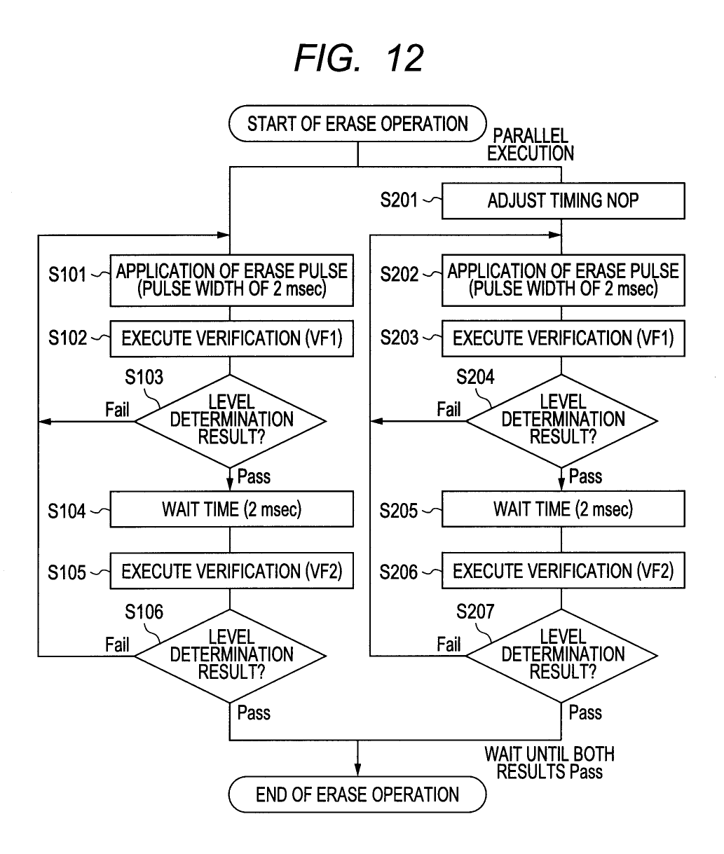

FIG. 12 shows a flow chart exemplifying the operation of the second embodiment. As shown in FIG. 12, in the second embodiment, when erase operation is started, the control circuit 5 supplies the address selection signal S01 for an erase pulse to the address circuit 3. In step S201, an adjustment circuit 16 in the control circuit 5 executes a timing adjustment not to apply the erase pulse at the same time to a plurality of memories. The control circuit 5 supplies the address selection signal S01 for an erase pulse to the address circuit 3 according to the adjusted timing. The address circuit 3 identifies a data erasing area based on the address selection signal S01 for an erase pulse. The address circuit 3 supplies the address signal S02 indicating address in the identified area to the first memory unit 2 and the second memory unit 11 at a different timing. In the subsequent steps, as is the case with the first embodiment, the erase operation is executed.

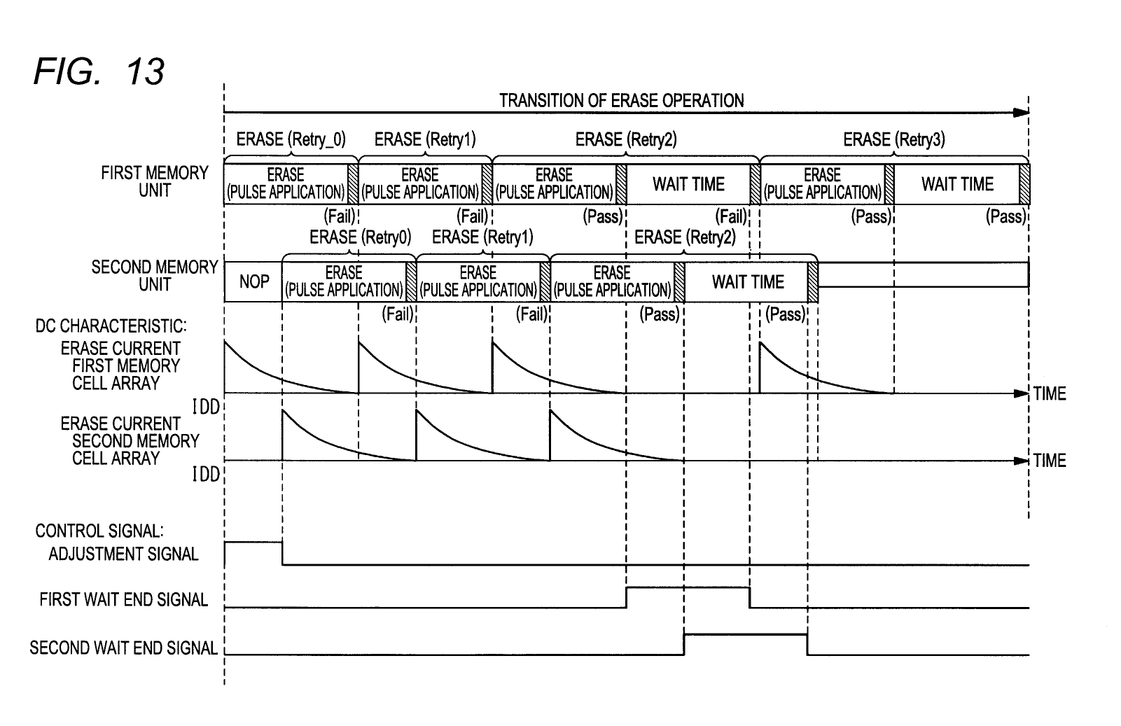

FIG. 13 shows a timing chart exemplifying the operation of the second embodiment. As shown in FIG. 13, the erase pulse is applied to the first memory unit 2. At this point, the adjustment circuit 16 issues a command (an adjustment signal) to bring the second memory unit 11 into a wait state. The adjustment circuit 16 releases the adjustment signal at the time a sudden inrush current caused by the erase operation in the first memory unit 2 reaches its peak and the erase pulse is applied also to the second memory unit 11.

In the nonvolatile semiconductor memory device 1 according to the second embodiment, the timing of the sudden inrush current at the time of starting the erase operation is shifted in the plurality of memory units (the first memory unit 2 and the second memory unit 11) to allow reducing the influence of occurrence of power supply noise caused by erasing. Furthermore, it is possible for the nonvolatile semiconductor memory device 1 according to the second embodiment to reduce the size of a power supply circuit supplying a necessary current.

In the nonvolatile semiconductor memory device 1 according to the second embodiment, erasing is performed for the plurality of memory units (the first memory unit 2 and the second memory unit 11) in a parallel manner. The erase operation of each memory unit is independently executed after the timing is adjusted. For this reason, even if the number of memory units further increases, the erase pulse can be applied with the peak of an inrush current shifted stepwise.

The embodiments of the present application are described in detail above. The invention in the present application is not limited to the above embodiments, but can be changed in various forms without departing from the spirit and scope of the present invention.

What is claimed is:

1. A method of operating a nonvolatile semiconductor memory, the method comprising:
applying an erase pulse to a data erase area in a memory cell array;
determining whether the threshold voltage of a memory cell arranged in the data erase area reaches an erase level and outputting a verify result;
determining whether a new erase pulse is applied or a wait command is issued based on the verify result; and
measuring the wait time during which an erase voltage is not applied in response to the wait command;
wherein determining whether the threshold voltage reaches the erase level occurs prior to issuing the wait command, the new erase pulse is applied when the threshold voltage does not reach the erase level, and the erase pulse is not applied and the wait command is issued when the threshold voltage reaches the erase level; and

2. The method of operating a nonvolatile semiconductor memory according to claim 1, further comprising:
executing verification after wait as to whether the threshold voltage in the data erase area maintains the erase level after the wait time passes;
applying a new erase pulse to the data erase area when the threshold voltage does not maintain the erase level as a result of executing the verification after wait;
executing the verification after the erasing after the application period during which the erase pulse is applied passes.

3. The method of operating a nonvolatile semiconductor memory according to claim 2, further comprising:
stopping applying the erase pulse during a new wait time if the threshold voltage maintains the erase level as a result of executing the verification after the new erasing;
after the steps above, executing the verification after the wait after the new wait time passes;

4. The method of operating a nonvolatile semiconductor memory according to claim 3, further comprising:
receiving a wait release command supplied in response to the wait time passing; and
wherein executing the verification after the wait occurs in response to the wait release command.

5. The method of operating a nonvolatile semiconductor memory according to claim 1,
wherein the memory cell array includes a first and a second memory cell arrays,
a first erase step of continuously applying an erase pulse for erasing data stored in the first memory cell array for a certain period; and
a second erase step of continuously applying an erase pulse for erasing data stored in the second memory cell array for a certain period,
a first verification-after-erase step of determining whether to erase data in the first memory cell array immediately after the execution of the first erase step; and
a second verification-after-erase step of determining whether to erase data in the second memory cell array immediately after the execution of the second erase step, and
wherein the first verification-after-erase step is different from the second verification-after-erase step in execution time.

6. A nonvolatile semiconductor memory device comprising:
a driver circuit configured to apply an erase pulse to a data erase area in a memory cell array;
a verify circuit configured to determine whether the threshold voltage of a memory cell arranged in the data erase area reaches an erase level and output a verify result;
a control circuit configured to determine whether a new erase pulse is applied or a state is shifted to a wait state based on the verify result; and
a wait circuit configured to measure the wait time during which an erase voltage is not applied in response to a wait command from the control circuit,
wherein the verify circuit determines whether the threshold voltage reaches the erase level before a state is shifted to the wait state after an application period during which the erase pulse is applied passes, and
wherein the control circuit instructs the driver circuit to apply the new erase pulse to the data erase area when the threshold voltage does not reach the erase level, and
instructs the driver circuit to prohibit the application of the new erase pulse, and issues the wait command to the wait circuit when the threshold voltage reaches the erase level.

7. The nonvolatile semiconductor memory device according to claim 6,
wherein the wait circuit issues a wait release command to the control circuit after the wait time passes,
wherein the control circuit issues a verify execution after-wait command to the verify circuit in response to the wait release command, and
wherein the verify circuit executes a determination as to whether the threshold voltage in the data erase area maintains the erase level in response to the verify execution after-wait command and outputs a new verify result.

8. The nonvolatile semiconductor memory device according to claim 7, wherein the control circuit identifies the application period so that the shift from a write level to an erase level is realized by applying the erase pulse a plurality of times.
